(19) United States
(12) Patent Application Publication
(10) Pub. No.: US 2014/0090468 A1
(43) Pub. Date: Apr. 3, 2014

(54) TRI-AXIAL MEMS INERTIAL SENSOR

(71) Applicant: Advanced NuMicro Systems, Inc., (US)

(72) Inventor: Yee-Chung Fu, Fremont, CA (US)

(73) Assignee: Advanced NuMicro Systems, Inc., San Jose, CA (US)

(21) Appl. No.: 13/844,956

(22) Filed: Mar. 16, 2013

Related U.S. Application Data
(60) Provisional application No. 61/612,227, filed on Mar. 16, 2012.

(51) Int. Cl. B81B 3/00; G01P 15/14

(52) U.S. Cl. CPC B81B 3/0021; G01P 15/14
USPC 73/504.08

(57) ABSTRACT

A micro-electromechanical systems (MEMS) inertial sensor includes first, second, and third fixed electrodes, a first translational element to translate along a first direction, first mobile electrodes extending from the first translation element and being interdigitated with the first fixed electrodes to form first sensor assemblies, a second translation element to translate along a second direction, second mobile electrodes extending from the second translation element and being interdigitated with the second fixed electrodes to form second sensor assemblies, and a rotation element to rotate about the second direction, the rotation element having a surface opposite the third fixed electrodes to form third sensor assemblies, wherein the third fixed electrode being displaced from the surface of the rotation element along a third direction.

### CROSS REFERENCE TO RELATED APPLICATION

This application claims priority to U.S. Provisional Patent Application No. 61/612,227, attorney docket no. ANS-P140-PV, filed Mar. 16, 2012, which is incorporated by reference in its entirety.

### BACKGROUND

U.S. Pat. No. 7,600,428 discloses a tri-axial membrane accelerometer. The proof-mass is vertically displaced from the membrane.

### BRIEF DESCRIPTION OF THE DRAWINGS

In the drawings:

FIG. 1A shows a perspective view of a tri-axial MEMS inertial sensor;

FIG. 1B shows a side view of the tri-axial MEMS inertial sensor of FIG. 1A; and

FIG. 2 shows a top view of a movable proof-mass and spring assembly, four stationary X-directional sensing comb assemblies, and two stationary Y-directional sensing comb assemblies, all arranged in accordance with embodiments of the present disclosure.

The same reference numbers appearing in different figures indicates similar or identical elements.

### DETAILED DESCRIPTION OF THE INVENTION

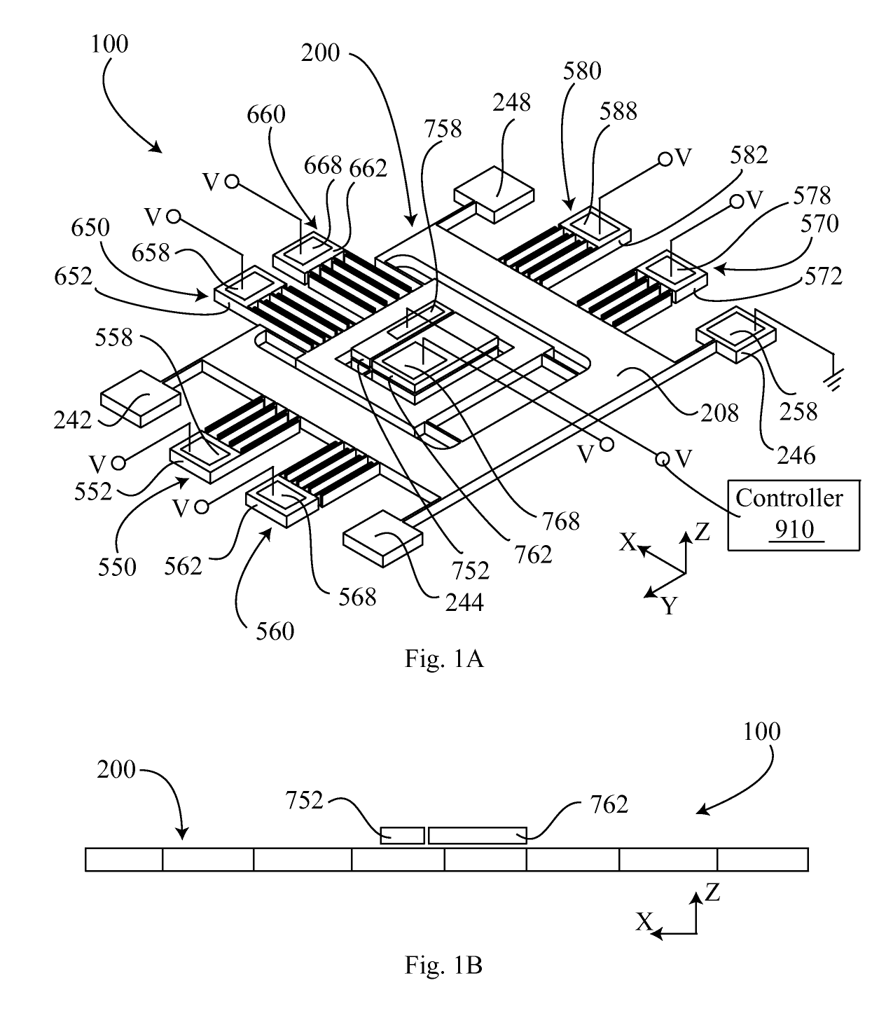

FIG. 1A shows a tri-axial micro-electromechanical systems (MEMS) inertial sensor 100 in one or more embodiments of the present disclosure. The inertial sensor 100 includes a movable proof-mass and spring assembly 200, six stationary comb assemblies 550, 560, 570, 580, 650 and 660, and two stationary electrode plates 752 and 762. In one embodiment, the proof-mass and spring assembly 200, the six stationary comb assemblies 550, 560, 570, 580, 650 and 660, and the two stationary electrode plates 752 and 762 are made of silicon. The movable proof-mass and spring assembly 200 has a top surface 208. The movable proof-mass and spring assembly 200 can move along a direction X, a direction Y, and a direction Z. The direction X and the direction Y are orthogonal to each other on a surface parallel to the top surface 208 of the movable proof-mass and spring assembly 200. The direction Z is perpendicular to the top surface 208 of the movable proof-mass and spring assembly 200. Four of the six stationary comb assemblies 550, 560, 570, and 580 are X-directional sensing comb assemblies. Two of the six stationary comb assemblies 650 and 660 are Y-directional sensing comb assemblies.

The six stationary comb assemblies 550, 560, 570, 580, 650 and 660 have six anchors 552, 562, 572, 582, 652, and 662 mounted to a device wafer. Six pads 558, 568, 578, 588, 658, and 668 are deposited on the six anchors 552, 562, 572, 582, 652, and 662 of the six stationary comb assemblies 550, 560, 570, 580, 650 and 660. Two pads 758 and 768 are deposited on the two stationary electrode plates 752 and 762. The eight pads 558, 568, 578, 588, 658, 668, 758 and 768 are hot. The movable proof-mass and spring assembly 200 has four anchors 242, 244, 246, and 248 mounted to the device wafer. One pad 258 is deposited on the anchor 246 of the movable proof-mass and spring assembly 200. The pad 258 connects to ground. In one embodiment, the nine pads 258, 558, 568, 578, 588, 658, 668, 758, and 768 are made of aluminum copper (AlCu). In another embodiment, the nine pads 258, 558, 568, 578, 588, 658, 668, 758, and 768 are further plated with nickel (Ni).

FIG. 1B shows the two stationary electrode plates 752 and 762 are vertically displaced from the movable proof-mass and spring assembly 200. Although not shown, there is a cover wafer bonded on the top surface of the device wafer on which the proof-mass and spring assembly 200 and stationary comb assemblies 550, 560, 570, 580, 650 and 660 are mounted. This cover wafer may be made of either silicon or glass. Metal may be deposited on the surface of the cover wafer facing the proof-mass 282 to form the stationary electrode plates 752 and 762.

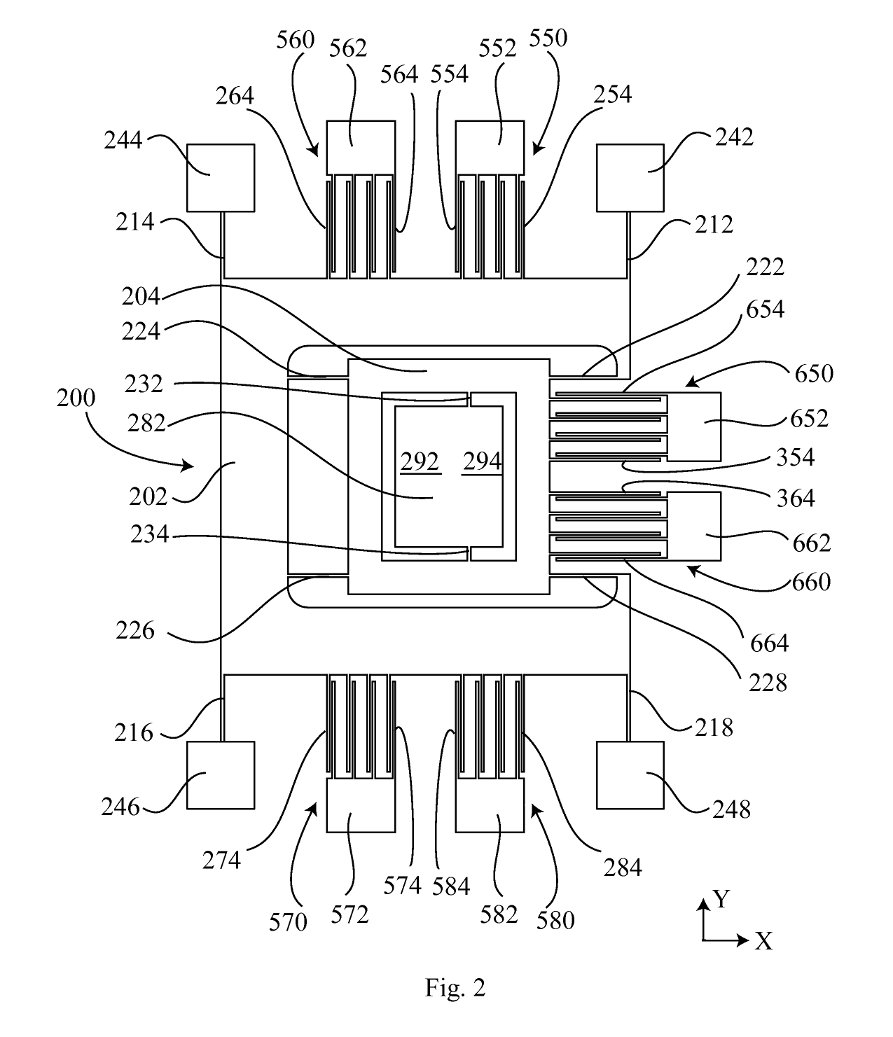

FIG. 2 shows a top view of the movable proof-mass and spring assembly 200, the four stationary X-directional sensing comb assemblies 550, 560, 570, and 580, and two stationary Y-directional sensing comb assemblies 650 and 660. In one embodiment, the movable proof-mass and spring assembly 200 has four X-directional springs 212, 214, 216, and 218, four Y-directional springs 222, 224, 226, and 228, two rotational or torsional springs 232 and 234, one outer frame 202, one inner frame 204, one proof-mass 282, four X-directional sensing comb sets 254, 264, 274, and 284, and two Y-directional sensing comb sets 354 and 364. The four X-directional springs 212, 214, 216, and 218 have lower stiffness in X-direction than those in Y-direction and in Z-direction. The four Y-directional springs 222, 224, 226, and 228 have lower stiffness in Y-direction than those in X-direction and in Z-direction. The four X-directional springs 212, 214, 216, and 218 connect the outer frame 202 to the four anchors 242, 244, 246, and 248 so the outer frame 202 is able to translate along the direction X. The four Y-directional springs 222, 224, 226, and 228 connect the inner frame 204 to the outer frame 202 so the inner frame 204 is able to translate along the direction Y. The two rotational springs 232 and 234 connect the proof-mass 282 to the inner frame 204 so the proof-mass 282 is able to rotate about the direction Z. The proof-mass 282 is unbalanced since the rotational springs 232 and 234 are connected to displace the axis of rotation from a principal inertia axis. The four X-directional sensing comb sets 254, 264, 274, and 284 extend out laterally from the outer frame 202. The two Y-directional sensing comb sets 354 and 364 extend out longitudinally from the inner frame 204. In another embodiment (not shown), the Y-directional springs connect the outer frame to the anchors. The X-directional springs connect the inner frame to the outer frame. The two rotational springs connect the proof-mass to the inner frame. The X-directional sensing comb sets extend out vertically from the inner frame. The Y-directional sensing comb sets extend out horizontally from the outer frame.

The four stationary X-directional sensing comb assemblies 550, 560, 570, and 580 have four X-directional sensing comb sets 554, 564, 574, and 584 extending out laterally from the four anchors 552, 562, 572, and 582. Each X-directional sensing comb set may consist of parallel electrode plates, also known as “fingers.” The four X-directional sensing comb sets 554, 564, 574, and 584 of the four X-directional sensing comb assemblies 550, 560, 570, and 580 interdigitate with the four X-directional sensing comb sets 254, 264, 274, and 284 of the movable proof-mass and spring assembly 200, respectively, to form first sensor assemblies. Each Y-directional sensing comb set may consist of fingers. Instead of two interdigitated comb sets being evenly spaced, the two interdigitated comb sets are offset in either a positive or negative X direction.

In one embodiment, the fingers in a pair of interdigitated X-directional sensing comb sets are offset in either the positive or the negative X direction. The fingers are offset in the positive X direction when the space between a mobile finger and its fixed neighboring finger (if any) in the positive X direction is smaller than the space between the mobile finger and its fixed neighbor (if any) in the negative X positive direction, which makes that pair of interdigitated pair of X-directional sensing comb sets more sensitive to translation along the positive X direction. Conversely the fingers are offset in the negative X direction when the space between a mobile finger and its fixed neighbor (if any) in the negative X direction is smaller than the space between the mobile finger and its fixed neighbor (if any) in the positive X positive direction, which makes that pair of interdigitated pair of X-directional sensing comb sets more sensitive to translation along the negative X direction. In one embodiment, the pair of the X-directional sensing comb sets 254 and 554 are offset in the positive X direction, the pair of the X-directional sensing comb sets 264 and 564 are offset in the negative X direction, the pair of the X-directional sensing comb sets 274 and 574 are offset in the negative X direction, and the pair of the X-directional sensing comb sets 284 and 584 are offset in the positive X direction.

The two stationary Y-directional sensing comb assemblies 650 and 660 have two Y-directional sensing comb sets 654 and 664 extending out longitudinally from the two anchors 652 and 662. Each Y-directional sensing comb set may consist of parallel fingers. The two Y-directional sensing comb sets 654 and 664 of the two Y-directional sensing comb assemblies 650 and 660 interdigitiate with the two Y-directional sensing comb sets 354 and 364 of the movable proof-mass and spring assembly 200, respectively, to form second sensor assemblies.

In one embodiment, the fingers in a pair of interdigitated Y-directional sensing comb sets are offset in either the positive or the negative Y direction. The fingers are offset in the positive Y direction when the space between a mobile finger and its fixed neighbor (if any) in the positive Y direction is smaller than the space between the mobile finger and its fixed neighbor (if any) in the negative Y positive direction, which makes that pair of interdigitated pair of Y-directional sensing comb sets more sensitive to translation along the positive Y direction. Conversely the fingers are offset in the negative Y direction when the space between a mobile finger and its fixed neighbor (if any) in the negative Y direction is smaller than the space between the mobile finger and its fixed neighbor in the positive Y positive direction, which makes that pair of interdigitated pair of Y-directional sensing comb sets more sensitive to translation along the negative Y direction. In one embodiment, the pair of the Y-directional sensing comb sets 354 and 654 are offset in the positive Y direction, and the pair of the Y-directional sensing comb sets 364 and 664 are offset in the negative Y direction.

The proof-mass 282 has left top surface 292 and right top surface 294. The left top surface 292 is on the left hand side of the two rotational springs 232 and 234, and is located opposite of the fixed electrode 762 that has substantially the same area. The right top surface 294 is on the right hand side of the two rotational springs 232 and 234, and is located opposite of the fixed electrode 752 that has substantially the same area. In one embodiment, the area of the left top surface 292 is large than that of the right top surface 294. In another embodiment, the area of the left top surface 292 is smaller than that of the right top surface 294.

The top surfaces 292 and 294 overlap the fixed electrodes 762 and 752, respectively, to form third sensor assemblies. The fixed electrode 752 is more sensitive to a clockwise rotation of the proof-mass 282 about the Y direction because in the clockwise rotation the gap between the top surface 294 of the proof-mass 282 and the fixed electrode 752 decrease. The fixed electrode 762 is more sensitive to a counterclockwise rotation of the proof-mass 282 about the Y direction because in the counterclockwise rotation the gap between the top surface 292 of the proof-mass 282 and the fixed electrode 762 decrease.

When the inertial sensor 100 experiences a X-direction acceleration, the four X-direction springs 212, 214, 216, and 218, the outer frame 202, the four Y-direction springs 222, 224, 226, and 228, the inner frame 204, the two rotational springs 232 and 234 and the proof-mass 282 move along the X-direction. The magnitude of the X-direction acceleration can be calculated from the change of the capacitance between the four X-directional sensing comb sets 554, 564, 574, and 584 of the four X-directional sensing comb assemblies 550, 560, 570, and 580 and the four X-directional sensing comb sets 254, 264, 274, and 284 of the movable proof-mass and spring assembly 200.

When the inertial sensor 100 experiences a Y-direction acceleration, the four Y-direction springs 222, 224, 226, and 228, the inner frame 204, the two rotational springs 232 and 234 and the proof-mass 282 move along the Y-direction. The magnitude of the Y-direction acceleration can be calculated from the change of the capacitance between the two Y-directional sensing comb sets 654, and 664 of the two Y-directional sensing comb assemblies 650 and 660 and the two Y-directional sensing comb sets 354 and 364 of the movable proof-mass and spring assembly 200.

When the inertial sensor 100 experiences a Z-direction acceleration, the proof-mass 282 rotates along the two rotational springs 232 and 234. The magnitude of the Z-direction acceleration can be calculated from the change of the capacitance between the two surfaces 292 and 294 of the proof-mass 282 and the two stationary electrode plates 752 and 762.

In one embodiment, the resonance frequencies of three mode shapes in X, Y, and Z directions of the movable proof-mass and spring assembly 200 are closely matched so a larger magnitude of motions may be achieved. The resonance frequencies are closely matched when there is less than 100 Hertz (Hz) or 10 Hz frequency difference.

While the movable proof-mass and spring assembly 200 is excited in the Z direction using electrostatic forces with a frequency near the Z direction resonance frequency, the movable proof-mass and spring assembly 200 moves under a Coriolis force along the Y direction if the inertial sensor 100 experiences a rotational about the X direction. The magnitude of the rotational speed in the X direction can be calculated from the change of the capacitance between the two Y-directional sensing comb sets 654, and 664 of the two Y-directional sensing comb assemblies 650 and 660 and the two Y-directional sensing comb sets 354 and 364 of the movable proof-mass and spring assembly 200.

While the movable proof-mass and spring assembly 200 is excited in the Z direction using electrostatic forces with a frequency near the Z direction resonance frequency, the movable proof-mass and spring assembly 200 moves under a Coriolis force along the X direction if the inertial sensor 100 experiences a rotational speed in the Y direction. The magnitude of the rotational speed in the Y direction can be calculated from the change of the capacitance between the four X-directional sensing comb sets 554, 564, 574, and 584 of the four X-directional sensing comb assemblies 550, 560, 570, and 580 and the four X-directional sensing comb sets 254, 264, 274, and 284 of the movable proof-mass and spring assembly 200.

While the movable proof-mass and spring assembly 200 is excited in the X direction using electrostatic forces with a frequency near the X direction resonance frequency, the movable proof-mass and spring assembly 200 moves under a Coriolis force along the Y direction if the inertial sensor 100 experiences a rotational speed in the Z direction. The magnitude of the rotational speed in the Z direction can be calculated from the change of the capacitance between the two Y-directional sensing comb sets 654, and 664 of the two Y-directional sensing comb assemblies 650 and 660 and the two Y-directional sensing comb sets 354 and 364 of the movable proof-mass and spring assembly 200.

The movable proof-mass and spring assembly 200 is excited in the Z and the X directions by driver circuits coupled to the sensing comb assemblies 550, 560, 570, and 580. The changes in capacitance are detected by sensing circuits coupled to the sensing comb assemblies 550, 560, 570, 580, 650, and 660, and electrode plates 752 and 762. The sensing and the driving of each X-directional sensing comb assemblies 550, 560, 570, and 580 may be performed on the same lead as the sensing is usually lower frequency and the driving is higher frequency. The driver circuit and the sensing circuit may be located on chip or off chip. A controller 910 may be connected to the capacitance circuits to determine capacitance changes and determine the magnitudes of the translational acceleration and rotational speed from the capacitance changes. The controller may be located on chip or off chip.

Various other adaptations of the embodiments disclosed are within the scope of the invention. For instance, using one X-directional sensing comb set instead of using four X-directional sensing comb sets. For instance, using one X-directional spring instead of using four X-directional springs. For instance, using serpentine springs instead of using linear springs.

1. A micro-electromechanical systems (MEMS) inertial sensor, comprising:
first fixed electrodes;
second fixed electrodes;
third fixed electrodes;
a first translation element to translate along a first direction;
first mobile electrodes extending from the first translation element and being interdigitated with the first fixed electrodes to form one or more first sensor assemblies;
a second translation element to translate along a second direction orthogonal to the first direction;
second mobile electrodes extending from the second translation element and being interdigitated with the second fixed electrodes to form one or more second sensor assemblies; and
a rotation element to rotate about the second direction, the rotation element having a surface opposite the third fixed electrodes to form one or more third sensor assemblies, the third fixed electrode being displaced from the surface of the rotation element along a third direction orthogonal to the first and the second directions.

2. The inertial sensor of claim 1, further comprising:
one or more sensing circuits coupled to the one or more first sensor assemblies, the one or more second sensor assemblies, and the one or more third sensor assemblies; and
a controller coupled to the one or more sensing circuits to:
determine a first capacitance change from the one or more first sensor assemblies, a second capacitance change from the one or more second sensor assemblies, and a third capacitance change from the one or more third sensor assemblies; and
determining a first acceleration of the inertial sensor along the first direction from the first capacitance change, a second acceleration of the inertial sensor along the second direction from the second capacitance change, and a third acceleration of the inertial sensor along the third direction from the third capacitance change.

3. The inertial sensor of claim 1, wherein:
the inertial sensor further comprises one or more fixed anchors, one or more first springs, one or more second springs, and one or more third springs;
the first translation element comprises an outer frame coupled by the one or more first springs to the one or more fixed anchors;
the second translation element comprises an inner frame coupled by the one or more second springs to the outer frame; and
the rotation element comprises a proof-mass coupled by the one or more third springs to the inner frame.

4. The inertial sensor of claim 3, wherein the one or more first springs have lower stiffness in the first direction than in the second and the third directions, the one or more second springs have lower stiffness in the second direction than in the first and the third directions, and the one or more third springs are torsional springs.

5. The inertial sensor of claim 3, wherein the proof-mass has a principal inertia axis and an axis of rotation displaced from the principal inertia axis so the proof-mass is unbalanced.

6. The inertial sensor of claim 3, wherein spacing of fixed and mobile electrodes in each of the first and the second sensor assemblies is offset in a positive or a negative direction so the sensor assembly is more sensitive in the positive or the negative direction.

7. The inertial sensor of claim 6, wherein the one or more first sensor assemblies include at least two sensor assemblies that are sensitive in positive and negative first directions, and the one or more second sensor assemblies include at least two sensor assemblies that are sensitive in positive and negative second direction.

8. The inertial sensor of claim 1, further comprising one or more driving circuits coupled to the one or more first sensor assemblies.

9. The inertial sensor of claim 8, wherein the first translation element, the first mobile electrodes, the second translation element, the second electrodes, and the rotation elements form a proof mass and spring assembly, and resonance frequencies of mode shapes in the first, the second, and the third directions of the proof mass and spring assembly closely matching.

10. The inertial sensor of claim 9, further comprising:
one or more sensing circuits coupled to the one or more first sensor assemblies, the one or more second sensor assemblies, and the one or more third sensor assemblies; and
a controller coupled to the one or more sensing circuits and the one or more driving circuits, wherein the controller being configured to:
excite the proof mass and spring assembly along the third direction at a resonance frequency in the third direction;
determine a first capacitance change from the one or more second sensor assemblies; and
determine a first speed of a first rotation of the inertial sensor about the first direction based on the first capacitance change.

11. The inertial sensor of claim 10, wherein the controller is further configured to:
excite the proof mass and spring assembly along the third direction at the resonance frequency in the third direction;
determine a second capacitance change from the one or more first sensor assemblies; and
determine a second speed of a second rotation of the inertial sensor about the second direction based on the second capacitance change.

12. The inertial sensor of claim 11, wherein the controller is further configured to:
excite the proof mass and spring assembly along the first direction at a resonance frequency in the first direction;
determine a third capacitance change from the one or more second sensor assemblies; and
determine a third speed of a third rotation of the inertial sensor about the third direction based on the third capacitance change.

13. A method for an inertial sensor, comprising:
determining a first acceleration of the inertial sensor along a first direction by capacitively sensing a first translation of a first translation element in the inertial sensor along the first direction;
determining a second acceleration of the inertial sensor along a second direction by capacitively sensing a second translation of a second translation element in the inertial sensor along the second direction, the second direction being orthogonal to the first direction; and
determining a third acceleration of the inertial sensor along a third direction by capacitively sensing a rotation of a rotation element in the inertial sensor about the second direction, the third direction being orthogonal to the first and the second directions.

14. The method of claim 13, further comprising:
exciting a proof mass and spring assembly along the third direction at a resonance frequency in the third direction; and
determining a first speed of a first rotation of the inertial sensor about the first direction by capacitively sensing a third translation of the second translation element.

15. The method of claim 14, further comprising:
exciting the proof mass and spring assembly along the third direction at the resonance frequency in the third direction; and
determining a second speed of a second rotation of the inertial sensor about the second direction by capacitively sensing a fourth translation along the first direction.

16. The method of claim 15, further comprising:
exciting the proof mass and spring assembly along the first direction at a resonance frequency in the first direction; and
determining a third speed of a third rotation of the inertial sensor about the third direction by capacitively sensing a fifth translation along the second direction.

17. The method of claim 16, wherein the first translation element, the second translation element, and the rotation elements form part of a proof mass and spring assembly, and resonance frequencies of mode shapes in the first, the second, and the third directions of the proof mass and spring assembly closely match.
